(19) United States
(12) Patent Application Publication
(10) Pub. No.: US 2022/0210913 A1
(43) Pub. Date: Jun. 30, 2022

(54) PRINTED CIRCUIT BOARD

(71) Applicant: SAMSUNG ELECTRO-MECHANICS CO., LTD., Suwon-si (KR)

(72) Inventors: Seon Ha KANG, Suwon-si (KR); Yong Hoon KIM, Suwon-si (KR)

(21) Appl. No.: 17/198,672

(22) Filed: Mar. 11, 2021

(30) Foreign Application Priority Data
Dec. 24, 2020 (KR) 10-2020-0182933

(51) Int. Cl. H05K 1/02

(52) U.S. Cl. CPC H05K 1/0298; H05K 1/115

(57) ABSTRACT

A printed circuit board includes: an insulating layer; a first circuit pattern embedded in one surface of the insulating layer; and a second circuit pattern disposed on the one surface of the insulating layer and including a first metal layer and a second metal layer disposed on the first metal layer. An average width of the first metal layer is wider than an average width of the second metal layer.

### CROSS-REFERENCE TO RELATED APPLICATION(S)

This application claims benefit of priority to Korean Patent Application No. 10-2020-0182933 filed on Dec. 24, 2020 in the Korean Intellectual Property Office, the disclosure of which is incorporated herein by reference in its entirety.

### TECHNICAL FIELD

The present disclosure relates to a printed circuit board.

### BACKGROUND

Performance improvements and miniaturization of a printed circuit board used in a mobile device or the like have been demanded, and accordingly, there is a need to efficiently utilize the area of a miniaturized printed circuit board.

At this time, an embedded circuit pattern embedded in an insulating layer may be formed in order to implement fine circuit patterns and vias included in the printed circuit board and arrange the same at high density.

### SUMMARY

An aspect of the present disclosure provides a printed circuit board that may be miniaturized.

Another aspect of the present disclosure provides a printed circuit board including fine circuit patterns arranged at high density.

According to an aspect of the present disclosure, a printed circuit board may include: an insulating layer; a first circuit pattern embedded in one surface of the insulating layer; and a second circuit pattern disposed on the one surface of the insulating layer and including a first metal layer and a second metal layer disposed on the first metal layer. An average width of the first metal layer may be wider than an average width of the second metal layer.

According to an aspect of the present disclosure, a printed circuit board may include: an insulating layer; a first circuit pattern embedded in one surface of the insulating layer; and a second circuit pattern disposed on the one surface of the insulating layer. A width of one surface of the second circuit pattern in contact with the one surface of the insulating layer may be wider than a width of another surface of the second circuit pattern opposing the one surface of the second circuit pattern.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a block diagram schematically illustrating an example of an electronic device system;

FIG. 2 is a plan view schematically illustrating an example of an electronic device;

FIG. 3 is a cross-sectional view schematically illustrating a printed circuit board according to an exemplary embodiment;

FIG. 4 is another enlarged view schematically illustrating a region of the printed circuit board according to the exemplary embodiment;

FIGS. 5A through 5L are views schematically illustrating a process for manufacturing the printed circuit board according to the exemplary embodiment; and

FIGS. 6A through 6L are views schematically illustrating another process for manufacturing the printed circuit board according to the exemplary embodiment.

### DETAILED DESCRIPTION

Hereinafter, exemplary embodiments of the present disclosure will now be described in detail with reference to the accompanying drawings.

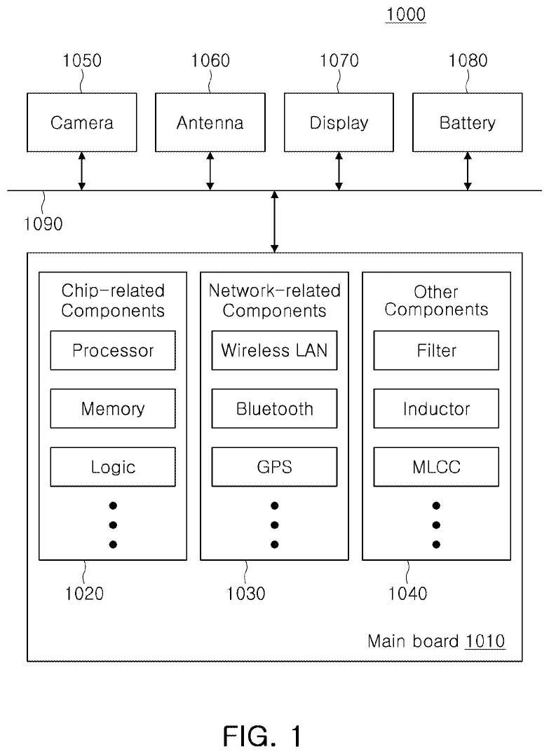

FIG. 1 is a block diagram schematically illustrating an example of an electronic device system.

Referring to FIG. 1, an electronic device 1000 may accommodate a main board 1010 therein. The main board 1010 may include chip-related components 1020, network-related components 1030, other components 1040, and the like, physically or electrically connected thereto. These components may be connected to others to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory; an application processor chip such as a central processor (for example, a central processing unit (CPU)), a graphics processor (for example, a graphics processing unit (GPU)), a digital signal processor, a cryptographic processor, a microprocessor, or a microcontroller; and a logic chip such as an analog-to-digital (ADC) converter or an application-specific integrated circuit (ASIC). However, the chip-related components 1020 are not limited thereto, but may also include other types of chip-related components. In addition, the chip-related components 1020 may be combined with each other. The chip-related components 1020 may be in a form of a package including the above-described chips or components.

The network-related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network-related components 1030 are not limited thereto, and may also include a variety of other wireless or wired standards or protocols. In addition, the network-related components 1030 may be combined with the chip-related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive elements in a form of a chip component used for various other purposes, or the like. In addition, other components 1040 may be combined with the chip-related components 1020 or the network-related components 1030 described above.

Depending on a type of the electronic device 1000, the electronic device 1000 may include other components that may or may not be physically or electrically connected to the main board 1010. Examples of other components include a camera module 1050, an antenna module 1060, a display 1070, and a battery 1080. However, other components are not limited thereto, but may include an audio codec, a video codec, a power amplifier, a compass, an accelerometer, a gyroscope, a speaker, amass storage device (for example, a hard disk drive), a compact disk (CD), a digital versatile disk (DVD), and the like. In addition, the electronic device 1000 may include other components used for various purposes depending on the type of the electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, but may be any other electronic device processing data.

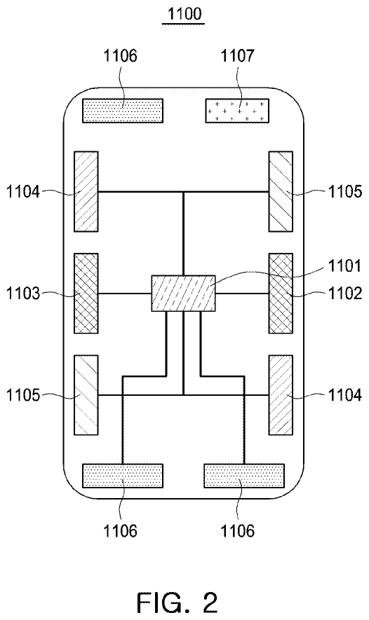

FIG. 2 is a plan view schematically illustrating an example of the electronic device.

Referring to FIG. 2, the electronic device may be, for example, a smartphone 1100. A modem 1101, and various types of antenna modules 1102, 1103, 1104, 1105, and 1106 connected to the modem 1101 through a rigid printed circuit board, a flexible printed circuit board, and/or a rigid-flexible printed circuit board may be disposed on the smartphone 1100. A wireless fidelity (Wi-Fi) module 1107 may also be disposed in the smartphone 1100, as needed. The antenna modules 1102, 1103, 1104, 1105, and 1106 may include antenna modules 1102, 1103, 1104, and 1005 for various frequency bands for 5G mobile communication, such as the antenna module 1102 for a frequency band of 3.5 GHz, the antenna module 1103 for a frequency band of 5 GHz, the antenna module 1104 for a frequency band of 28 GHz, and the antenna module 1105 for a frequency band of 39 GHz, and may also include the antenna module 1106 for 4G, but are not limited thereto. Meanwhile, the electronic device is not necessarily limited to the smartphone 1100, but may be other electronic devices as described above.

### Printed Circuit Board

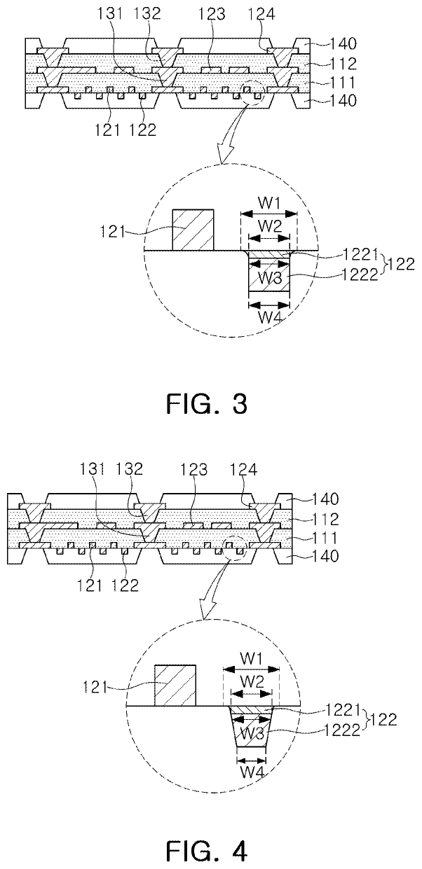

FIG. 3 is a cross-sectional view schematically illustrating a printed circuit board according to an exemplary embodiment.

Referring to FIG. 3, the printed circuit board may include insulating layers 111 and 112, circuit patterns 121, 122, 123, and 124, and vias 131 and 132, and may further include a passivation layer 140.

The insulating layers 111 and 112 may be a plurality of insulating layers 111 and 112, the circuit patterns 121, 122, 123, and 124 may be a plurality of circuit patterns 121, 122, 123, and 124, and the vias 131 and 132 may be a plurality of vias 131 and 132.

Specifically, the printed circuit board may include a first insulating layer 111, first circuit patterns 121 embedded in one surface of the first insulating layer 111, second circuit patterns 122 disposed on the one surface of the first insulating layer 111, third circuit patterns 123 disposed on the other surface opposite to the one surface of the first insulating layer 111, first vias 131 penetrating through the first insulating layer 111 and connecting the third circuit patterns 123 and the first circuit patterns 121 to each other, a second insulating layer 112 disposed on the other surface of the first insulating layer 111 and covering the third circuit patterns 123, fourth circuit patterns 124 disposed on the second insulating layer 112, and second vias 132 penetrating through the second insulating layer 112 and connecting the fourth circuit patterns 124 and the third circuit patterns 123 to each other.

Further, the first circuit patterns 121, the second circuit patterns 122, the third circuit patterns 123, and the fourth circuit patterns 124 may each be a plurality of circuit patterns disposed on the same layer so as to be spaced apart from each other. For example, the first circuit patterns 121 may be a plurality of first circuit patterns 121 disposed on the same layer so as to be spaced apart from each other, the second circuit patterns 122 may be a plurality of second circuit patterns 122 disposed on the same layer so as to be spaced apart from each other, the third circuit patterns 123 may be a plurality of third circuit patterns 123 disposed on the same layer so as to be spaced apart from each other, and the fourth circuit patterns 124 may be a plurality of fourth circuit patterns 124 disposed on the same layer so as to be spaced apart from each other.

However, it is a matter of course that the number of the plurality of insulating layers 111 and 112, the number of plurality of circuit patterns 121, 122, 123, and 124, and the number of plurality of vias 131 and 132 are not limited to those illustrated in the drawings. Further, it is a matter of course that the number of plurality of first circuit patterns 121, the number of plurality of second circuit patterns 122, the number of plurality of third circuit patterns 123, and the number of plurality of fourth circuit patterns 124 are also not limited to those illustrated in the drawings.

Meanwhile, the printed circuit board according to the exemplary embodiment includes both of the first circuit patterns 121 embedded in the one surface of the first insulating layer 111, and the second circuit patterns 122 disposed on the one surface of the first insulating layer 111. Here, the first circuit patterns 121 and the second circuit patterns 122 may be disposed so as to be misaligned with each other, thereby configuring different wiring layers. Therefore, the circuit patterns may be arranged at high density by forming the first circuit patterns 121 and the second circuit patterns 122, which are a plurality of circuit patterns, in and on the one surface of the first insulating layer 111. As a result, the printed circuit board may be miniaturized.

Here, at least one of a line width of the first circuit pattern 121 or a line width of the second circuit pattern 122 may be smaller than at least one of a line width of the third circuit pattern 123 or a line width of the fourth circuit pattern 124. For example, the line width of the first circuit pattern 121 and the line width of the second circuit pattern 122 may be smaller than the line width of the third circuit pattern 123 and the line width of the fourth circuit pattern 124, respectively. That is, the first circuit pattern 121 and the second circuit pattern 122 may be fine circuit patterns.

Meanwhile, the first circuit pattern 121 may include one metal layer. As described later, the first circuit pattern 121 may be formed by performing plating on a metal foil included in a carrier substrate, and then, the first circuit pattern 121 may be formed to include only one metal layer by removing the metal foil disposed thereon by etching or the like.

The first circuit pattern 121 may have a surface coplanar with the one surface of the first insulating layer 111. However, when removing the metal foil disposed on the first circuit pattern 121 by etching or the like, a part of the first circuit pattern 121 may be etched together. In this case, the first circuit pattern 121 may be positioned more inward than the one surface of the first insulating layer 111 is.

The second circuit pattern 122 may include a first metal layer 1221 and a second metal layer 1222 disposed on the first metal layer 1221. As described later, the second circuit pattern 122 may be formed by performing plating on a metal foil included in a carrier substrate, and then, the second circuit pattern 122 may be formed to include a plurality of metal layers by not removing the metal foil disposed thereon. However, the second circuit pattern 122 may include metal layers more than those illustrated in the drawings. For example, the second circuit pattern 122 may further include a third metal layer disposed between the first metal layer 1221 and the second metal layer 1222.

A thickness of the first metal layer 1221 may be smaller than a thickness of the second metal layer 1222. As described later, the first metal layer 1221 may be a metal foil attached to a carrier substrate, and may function as a seed layer at the time of forming the first circuit pattern 121 and the second metal layer 1222.

The first metal layer 1221 may have a surface coplanar with the one surface of the first insulating layer 111. For example, such a structure may be implemented by forming the first circuit pattern 121 on a metal foil of a carrier substrate, laminating the first insulating layer 111, forming the second metal layer 1222 on a surface opposite to a surface of the metal foil on which the first circuit pattern 121 is formed, and then removing the metal foil in a region other than a region corresponding to the second metal layer 1222 to form the first metal layer 1221. As another example, such a structure may also be implemented by forming the first circuit pattern 121 on a metal foil of a carrier substrate, laminating the first insulating layer 111, forming a plating layer on a surface opposite to a surface of the metal foil on which the first circuit pattern 121 is formed, and then etching the metal foil and the plating layer to form the first metal layer 1221 and the second metal layer 1222.

In a same second circuit pattern 122, an average width of the first metal layer 1221 may be wider than an average width of the second metal layer 1222. The average width may mean the arithmetic mean at n arbitrary points. Further, a width W1 of one surface of the first metal layer 1221 that faces the first insulating layer 111 may be wider than a width W2 of the other surface of the first metal layer 1221 that is opposite to the one surface of the first metal layer 1221.

As described above, the first metal layer 1221 may be a metal foil attached to a carrier substrate. Since a speed of etching the metal foil is relatively lower than a speed of etching the plating layer, a degree to which the one surface of the metal layer 1221 is etched is relatively lower than a degree to which the other surface of the first metal layer 1221 is etched. As a result, the width W1 of the one surface of the first metal layer 1221 may be wider than the width W2 of the other surface.

A method for forming the second metal layer 1222 is not particularly limited. However, the second metal layer 1222 may be formed by performing electroplating or electroless plating on the first metal layer 1221.

A width W3 of one surface of the second metal layer 1222 that faces the first metal layer 1221 may be substantially the same as or similar to a width W4 of the other surface of the second metal layer 1222 that is opposite to the one surface of the second metal layer 1222. Ina similar aspect, a difference between the width W3 of the one surface of the second metal layer 1222 and the width W4 of the other surface of the second metal layer 1222 may be smaller than a difference between the width W1 of the one surface of the first metal layer 1221 and the width W2 of the other surface of the first metal layer 1221.

As described later, the second metal layer 1222 may be formed by a semi additive process (SAP). In this case, a structure in which the width W3 of the one surface of the second metal layer 1222 that faces the first metal layer 1221 is substantially the same or similar to the width W4 of the other surface of the second metal layer 1222 that is opposite to the one surface of the second metal layer 1222 may be implemented by disposing a plating resist having an opening in a region in which the first metal layer 1222 is formed, and performing plating to fill the opening.

The passivation layer 140 may be disposed on the one surface of the first insulating layer 111 and cover the second circuit patterns 122. The passivation layer 140 may have an opening through which the first circuit pattern 121 is at least partially exposed.

The passivation layer 140 may be a solder resist, but is not limited thereto, and a known insulating material may be used for the passivation layer 140.

Meanwhile, an insulating material generally used for an insulating layer of a substrate may be used to form the insulating layers 111 and 112 without limitation. The material of each of the insulating layers 111 and 112 may be at least one of an epoxy resin, a bismaleimide-based resin, a resin in which the epoxy resin and the bismaleimide-based resin are impregnated together with an inorganic filler such as silica (SiO₂) in a core material such as a glass fiber (or a glass cloth or a glass fabric), prepreg, Ajinomoto Build up Film (ABF), FR-4, or Bismaleimide Triazine (BT). The materials of the plurality of insulating layers 111 and 112 may be the same as each other or different from each other.

A material of each of the circuit patterns 121, 122, 123, and 124 may be a conductive material. For example, the material of each of the circuit patterns 121, 122, 123, and 124 may be copper (Cu), aluminum (Al), silver (Ag), tin (Sn), gold (Au), nickel (Ni), lead (Pb), titanium (Ti), or alloys thereof. The materials of the plurality of circuit patterns 121, 122, 123, and 124 may be the same as each other or different from each other.

A material of each of the vias 131 and 132 may be a conductive material such as copper (Cu), aluminum (Al), silver (Ag), tin (Sn), gold (Au), nickel (Ni), lead (Pb), titanium (Ti), or alloys thereof. Each of the vias 131 and 132 may be a filled-type via completely filled with the conductive material, or the conductive material may be formed along a wall of each of via holes. In a case where the conductive material is formed along the wall of each of the via holes of the vias 131 and 132, the via hole may be filled with an insulating material. Each of the vias 131 and 132 may have a known shape such as a cylindrical shape or a tapered shape. The materials and/or shapes of the plurality of vias 131 and 132 may be the same as each other or different from each other.

FIG. 4 is another enlarged view schematically illustrating a region of the printed circuit board according to the exemplary embodiment.

Referring to FIG. 4, the width W3 of one surface of the second metal layer 1222 that faces the first metal layer 1221 may be wider than the width W4 of the other surface of the second metal layer 1222 that is opposite to the one surface of the second metal layer 1222. Therefore, the second circuit pattern 122 may have a structure whose width is increased in a direction from the second metal layer 1222 toward the first metal layer 1221. However, the second circuit pattern 122 may have at least one region whose width is decreased in a direction from the second metal layer 1222 toward the first metal layer 1221.

As described later, in a case where the second circuit pattern 122 including the first metal layer 1221 and the second metal layer 1222 is formed by applying a subtractive method such as tenting, an etching speed may be lowered in a direction from the second metal layer 1222, which is a surface layer of the second circuit pattern 122, toward the first metal layer 1221, which is an inner layer of the second circuit pattern 122, thereby implementing such a structure.

In this case, a difference between the width W3 of the one surface of the second metal layer 1222 and the width W4 of the other surface of the second metal layer 1222 may be smaller than a difference between the width W1 of the one surface of the first metal layer 1221 and the width W2 of the other surface of the first metal layer 1221. The second metal layer 1222 may be a plating layer, and the first metal layer 1221 may be a metal foil. Since a speed of etching the metal foil is relatively lower than a speed of etching the plating layer, a structure in which the difference between the width W1 of the one surface of the first metal layer 1221 and the width W2 of the other surface of the first metal layer 1221 may be larger than the difference between the width W3 of the one surface of the second metal layer 1222 and the width W4 of the other surface of the second metal layer 1222.

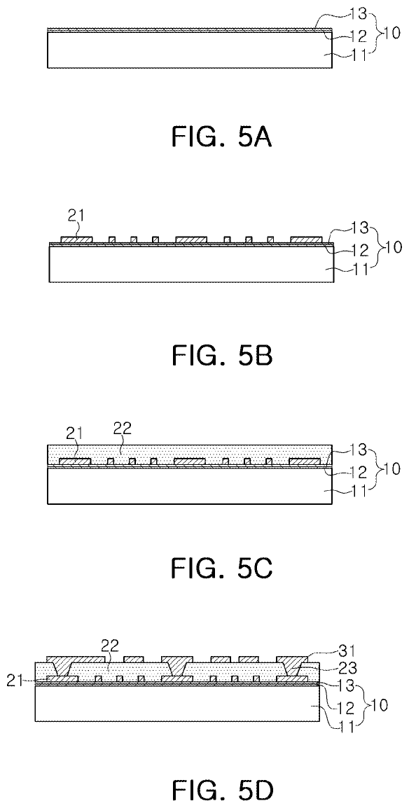

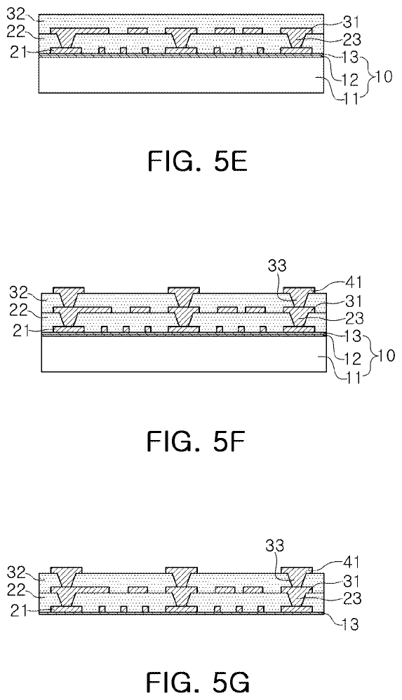

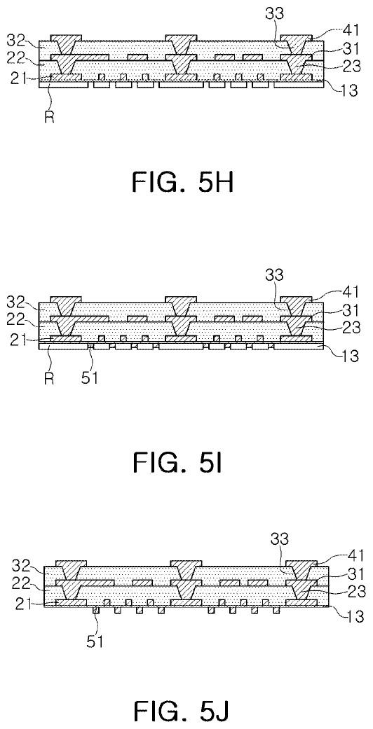

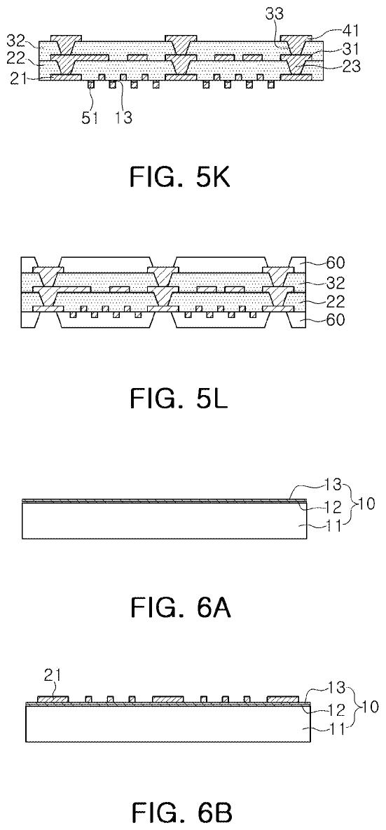

FIGS. 5A through 5L are views schematically illustrating a process for manufacturing the printed circuit board according to the exemplary embodiment.

Referring to FIG. 5A, a carrier substrate 10, in which a first metal foil 12 and a second metal foil 13 are disposed on one surface or opposite surfaces of the insulating substrate 11, is prepared. Here, a release layer may be additionally disposed between the first metal foil 12 and the second metal foil 13.

Referring to FIG. 5B, first circuit patterns 21 are formed on the second metal foil 13. The second metal foil 13 may function as a seed layer, and the first circuit patterns 21 may be formed by performing electroplating or the like.

Referring to FIG. 5C, a first insulating layer 22 are laminated on the first circuit patterns 21.

Referring to FIG. 5D, first vias 23 and third circuit patterns 31 are formed in and on the first insulating layer 22. The first vias 23 and the third circuit patterns 31 may be formed by forming via holes in the first insulating layer 22, forming an electroless plating layer on a surface of the first insulating layer 22 and a wall surface of each of the via holes, and then forming an electroplating layer on the electroless plating layer.

Referring to FIG. 5E, a second insulating layer 32 is laminated on the first insulating layer 22 so as to cover the third circuit patterns 31.

Referring to FIG. 5F, second vias 33 and fourth circuit patterns 41 are formed in and on the second insulating layer 32. The second vias 33 and the fourth circuit patterns 41 may be formed by forming via holes in the second insulating layer 32, forming an electroless plating layer on a surface of the second insulating layer 32 and a wall surface of each of the via holes, and then forming an electroplating layer on the electroless plating layer.

Referring to FIG. 5G, the first metal foil 12 and the second metal foil 13 are separated from each other.

Referring to FIG. 5H, a plating resist R having an opening is disposed on the second metal foil 13. The opening is formed in a region corresponding to a region in which a plating layer 51 to be described later is formed.

Referring to FIG. 5I, the plating layer 51 is formed in the opening of the resist R. The plating layer 51 may be formed by performing electroplating on the second metal foil 13.

Referring to FIG. 5J, the resist R may be removed by delamination or the like.

Referring to FIG. 5K, the second metal foil 13 formed in a region other than the region in which the plating layer 51 is formed is removed by etching or the like. That is, the second circuit pattern including the second metal foil 13 and the plating layer 51 is formed by the semi additive process in the process for manufacturing the printed circuit board according to the exemplary embodiment.

Here, as described above, the fourth circuit pattern may include an electroless plating layer and an electroplating layer, and an electroless plating layer formed in a region other than a region in which the fourth circuit patterns 41 are formed may be removed together.

Referring to FIG. 5L, a passivation layer 60 is formed. The passivation layer 60 may be formed by applying a solder resist ink or the like.

Although reference numerals different from those in FIG. 3 or FIG. 4 are used in FIGS. 5A-5L, the printed circuit board shown in FIG. 3 or FIG. 4 may be formed based on the manufacturing process shown in FIGS. 5A-5L.

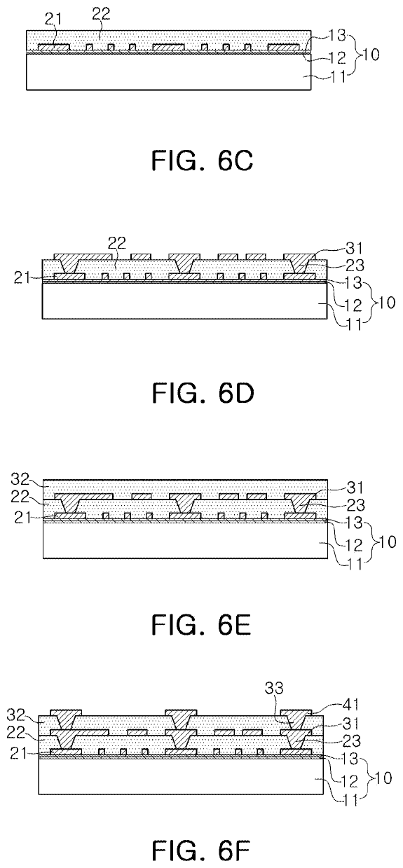

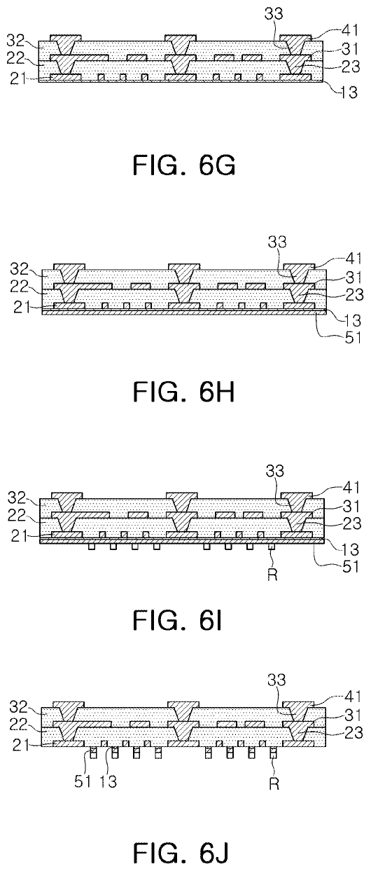

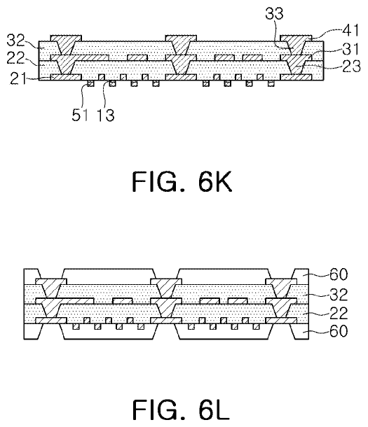

FIGS. 6A through 6L are views schematically illustrating another process for manufacturing the printed circuit board according to the exemplary embodiment.

Referring to FIG. 6A, a carrier substrate 10, in which a first metal foil 12 and a second metal foil 13 are disposed on one surface or opposite surfaces of the insulating substrate 11, is prepared. Here, a release layer may be additionally disposed between the first metal foil 12 and the second metal foil 13.

Referring to FIG. 6B, first circuit patterns 21 are formed on the second metal foil 13. The second metal foil 13 may function as a seed layer, and the first circuit patterns 21 may be formed by performing electroplating or the like.

Referring to FIG. 6C, a first insulating layer 22 may be laminated on the first circuit patterns 21.

Referring to FIG. 6D, first vias 23 and third circuit patterns 31 may be formed in and on the first insulating layer 22. The first vias 23 and the third circuit patterns 31 may be formed by forming via holes in the first insulating layer 22, forming an electroless plating layer on a surface of the first insulating layer 22 and a wall surface of each of the via holes, and then forming an electroplating layer on the electroless plating layer.

Referring to FIG. 6E, a second insulating layer 32 is laminated on the first insulating layer 22 so as to cover the third circuit patterns 31.

Referring to FIG. 6F, second vias 33 and fourth circuit patterns 41 are formed in and on the second insulating layer 32. The second vias 33 and the fourth circuit patterns 41 may be formed by forming via holes in the second insulating layer 32, forming an electroless plating layer on a surface of the second insulating layer 32 and a wall surface of each of the via holes, and then forming an electroplating layer on the electroless plating layer.

Referring to FIG. 6G, the first metal foil 12 and the second metal foil 13 are separated from each other.

Referring to FIG. 6H, a plating layer 51 is formed on the second metal foil 13. The plating layer 51 may be formed by performing electroplating on the second metal foil 13.

Referring to FIG. 6I, a resist R having an opening is disposed on the plating layer 51. The opening may be formed in a region other than a region corresponding to the second circuit patterns.

Referring to FIG. 6J, the second metal foil 13 and the plating layer 51 disposed in a region other than the region corresponding to the second circuit patterns are removed by etching or the like. That is, the second circuit pattern including the second metal foil 13 and the plating layer 51 is formed by the tenting in the process for manufacturing the printed circuit board according to the exemplary embodiment.

Referring to FIG. 6K, the resist R may be removed by delamination or the like.

Referring to FIG. 6L, a passivation layer 60 is formed. The passivation layer 60 may be formed by applying a solder resist ink or the like.

Although reference numerals different from those in FIG. 3 or FIG. 4 are used in FIGS. 6A-6L, the printed circuit board shown in FIG. 3 or FIG. 4 may be formed based on the manufacturing process shown in FIGS. 6A-6L.

However, it is a matter of course that the process for manufacturing the printed circuit board according to the present disclosure is not limited to that described above in the present specification.

As set forth above, according to the exemplary embodiment in the present disclosure, the printed circuit board that may be miniaturized may be provided.

In addition, the printed circuit board including the fine circuit patterns arranged at high density may be provided.

While exemplary embodiments have been shown and described above, it will be apparent to those skilled in the art that modifications and variations could be made without departing from the scope of the present disclosure as defined by the appended claims.

What is claimed is:

1. A printed circuit board comprising:
an insulating layer;
a first circuit pattern embedded in one surface of the insulating layer; and
a second circuit pattern disposed on the one surface of the insulating layer and including a first metal layer and a second metal layer disposed on the first metal layer,
wherein an average width of the first metal layer is wider than an average width of the second metal layer.

2. The printed circuit board of claim 1, wherein a width of one surface of the first metal layer that faces the insulating layer is wider than a width of the other surface of the first metal layer that is opposite to the one surface of the first metal layer.

3. The printed circuit board of claim 1, wherein a width of one surface of the second metal layer that faces the first metal layer is wider than a width of the other surface of the second metal layer that is opposite to the one surface of the second metal layer.

4. The printed circuit board of claim 1, wherein a thickness of the first metal layer is smaller than a thickness of the second metal layer.

5. The printed circuit board of claim 1, wherein the first metal layer has a surface coplanar with the one surface of the insulating layer.

6. The printed circuit board of claim 1, further comprising a third circuit pattern disposed on the other surface of the insulating layer that is opposite to the one surface of the insulating layer,
wherein at least one of a line width of the first circuit pattern or a line width of the second circuit pattern is smaller than a line width of the third circuit pattern.

7. The printed circuit board of claim 1, wherein the first circuit pattern includes one metal layer.

8. The printed circuit board of claim 1, wherein the first circuit pattern and the second circuit pattern are disposed so as to be misaligned with each other.

9. The printed circuit board of claim 1, further comprising a passivation layer disposed on the one surface of the insulating layer and covering the second circuit pattern.

10. The printed circuit board of claim 9, wherein the passivation layer covers an entirety of the second circuit pattern.

11. The printed circuit board of claim 1, wherein the first circuit pattern and the second circuit pattern are alternately disposed.

12. A printed circuit board comprising:
an insulating layer;
a first circuit pattern embedded in one surface of the insulating layer; and
a second circuit pattern disposed on the one surface of the insulating layer,
wherein a width of one surface of the second circuit pattern in contact with the one surface of the insulating layer is wider than a width of another surface of the second circuit pattern opposing the one surface of the second circuit pattern.

13. The printed circuit board of claim 12, further comprising a third circuit pattern disposed on the other surface of the insulating layer that is opposite to the one surface of the insulating layer,
wherein at least one of a line width of the first circuit pattern or a line width of the second circuit pattern is smaller than a line width of the third circuit pattern.

14. The printed circuit board of claim 12, further comprising a passivation layer disposed on the one surface of the insulating layer and covering the second circuit pattern.

15. The printed circuit board of claim 14, wherein the passivation layer covers an entirety of the second circuit pattern.

16. The printed circuit board of claim 14, wherein the first circuit pattern and the second circuit pattern are alternately disposed at an interface between the passivation layer and the insulating layer.
